(19) United States
(12) Patent Application Publication
(10) Pub. No.: US 2021/0296569 A1
(43) Pub. Date: Sep. 23, 2021

(54) MAGNETORESISTANCE MEMORY DEVICE AND MANUFACTURING METHOD OF MAGNETORESISTANCE MEMORY DEVICE

(71) Applicant: Kioxia Corporation, Tokyo (JP)

(72) Inventor: Yasuyuki SONODA, Seoul (KR)

(73) Assignee: Kioxia Corporation, Tokyo (JP)

(21) Appl. No.: 17/198,454

(22) Filed: Mar. 11, 2021

(30) Foreign Application Priority Data
Mar. 19, 2020 (JP) 2020-048781

(51) Int. Cl. H01L 43/02; H01L 43/12; G11C 11/16; H01L 27/22

(52) U.S. Cl. CPC H01L 43/02; H01L 43/12; H01L 43/10; H01L 27/228; G11C 11/161

(57) ABSTRACT

In general, according to one embodiment, a magnetoresistance memory device comprising includes: a layer stack including a first ferromagnetic layer, a second ferromagnetic layer, and an insulating layer between the first ferromagnetic layer and the second ferromagnetic layer; a first nitride on a side surface of the layer stack; a first layer on a side surface of the first nitride; a second layer on a side surface of the first layer, a first electrode on the layer stack; and a second nitride on a side surface of the second layer. The second layer is in contact with the first layer at a position above an upper surface of the first layer.

### CROSS-REFERENCE TO RELATED APPLICATIONS

This application is based upon and claims the benefit of priority from Japanese Patent Application No. 2020-048781, filed Mar. 19, 2020, the entire contents of which are incorporated herein by reference.

### FIELD

Embodiments described herein relate generally to a magnetoresistance memory device.

### BACKGROUND

Magnetoresistance memory devices using a magnetoresistance effect element are known.

### BRIEF DESCRIPTION OF THE DRAWINGS

FIG. 1 shows functional blocks of a magnetoresistance memory device according to a first embodiment.

FIG. 2 is a circuit diagram of a memory cell of the first embodiment.

FIG. 3 shows a cross-sectional structure of part of the memory cell of the first embodiment.

FIGS. 4 to 12 sequentially show structures of part of the memory cell of the first embodiment during a process of manufacturing the same.

### DETAILED DESCRIPTION

In general, according to one embodiment, a magnetoresistance memory device comprising includes: a layer stack including a first ferromagnetic layer, a second ferromagnetic layer, and an insulating layer between the first ferromagnetic layer and the second ferromagnetic layer; a first nitride on a side surface of the layer stack; a first layer on a side surface of the first nitride; a second layer on a side surface of the first layer, a first electrode on the layer stack; and a second nitride on a side surface of the second layer. The second layer is in contact with the first layer at a position above an upper surface of the first layer.

Embodiments will now be described with reference to the figures. In the following description, components with substantially the same functionalities and configurations will be referred to by the same reference numerals, and repeated descriptions may be omitted. The figures are schematic, and the relation between the thickness and the area of a plane of a layer and the ratio of thicknesses of layers may differ from the actual ones.

The entire description of a particular embodiment also applies to another embodiment unless explicitly mentioned otherwise or obviously eliminated. Each embodiment illustrates a device and a method for materializing the technical idea of that embodiment, and the technical idea of each embodiment does not limit the quality of the material, shape, structure, arrangement of components, etc. to those that will be described below.

In the specification and the claims, when a particular first component is expressed as being “coupled” to another second component, the first component may be coupled to the second component either directly or via one or more components which are always or selectively conductive.

The embodiments will be described by using an xyz orthogonal coordinate system. In the description below, the term “below” as well as the terms derived therefrom and the terms related thereto refer to a position having a smaller coordinate on the z-axis, and the term “above” as well as the terms derived therefrom and the terms related thereto refer to a position having a larger coordinate on the z-axis.

### First Embodiment

### 1. Structure (Configuration)

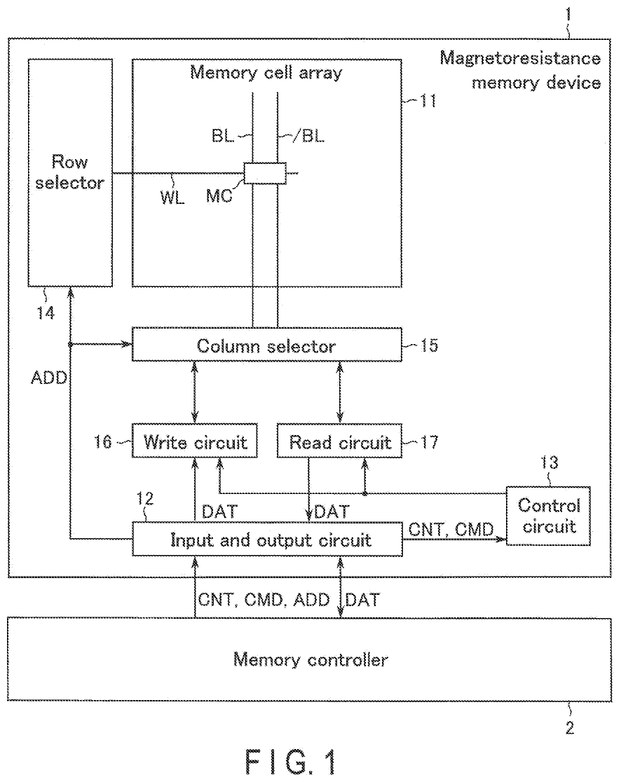

FIG. 1 shows functional blocks of a magnetoresistance memory device according to a first embodiment. As shown in FIG. 1, a magnetoresistance memory device 1 includes a memory cell array 11, an input and output circuit 12, a control circuit 13, a row selector 14, a column selector 15, a write circuit 16, and a read circuit 17.

The memory cell array 11 includes memory cells MC, word lines WL, bit lines BL, and bit lines /BL. A single bit line BL and a single bit line /BL constitute a bit line pair.

The memory cell MC can store data in a non-volatile manner. Each memory cell MC is coupled to a single word line WL and a pair of bit lines BL and /BL. Each word line WL is associated with a row. Each pair of bit lines BL and /BL is associated with a column. Selection of a single row and selection of one or more columns specify one or more memory cells MC.

The input and output circuit 12 receives a control signal CNT of various types, a command CMD of various types, an address signal ADD, and data (write data) DAT, for example, from a memory controller 2, and transmits data (read data) DAT to, for example, the memory controller 2.

The row selector 14 receives the address signal ADD from the input and output circuit 12, and brings one word line WL associated with the row that is specified by the received address signal ADD into a selected state.

The column selector 15 receives the address signal ADD from the input and output circuit 12 and brings bit lines BL associated with one or more columns that are specified by the received address signal ADD into a selected state.

The control circuit 13 receives the control signal CNT and the command CMD from the input and output circuit 12. The control circuit 13 controls the write circuit 16 and the read circuit 17 based on control instructed by the control signal CNT and the command CMD. Specifically, the control circuit 13 supplies voltages used for data writing to the write circuit 16 during the data writing to the memory cell array 11. Further, the control circuit 13 supplies voltages used for data reading to the read circuit 17 during the reading of data from the memory cell array 11.

The write circuit 16 receives write data DAT from the input and output circuit 12 and supplies the voltages used for data writing to the column selector 15 based on the control by the control circuit 13 and the write data DAT.

The read circuit 17 includes a sense amplifier, and based on the control of the control circuit 13, uses the voltages used for data reading to determine data stored in the memory cells MC. The determined data is supplied to the input and output circuit 12 as the read data DAT.

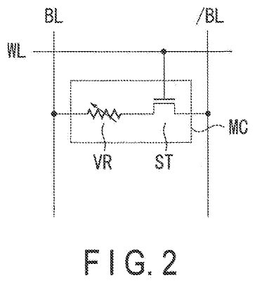

FIG. 2 is a circuit diagram of a memory cell MC of the first embodiment. The memory cell MC includes a magnetoresistance effect element VR and a select transistor ST. The magnetoresistance effect element VR exhibits a magnetoresistance effect, and includes, for example, a magnetic tunnel junction (MTJ) element. The MTJ element refers to a structure including an MTJ. In a steady state, the variable resistance element VR can be in a selected resistance state of two resistance states, and the resistance of one of the two resistance states is higher than the resistance of the other. The magnetoresistance effect element VR can switch between the low resistance state and the high resistance state, and can store one bit of data using the difference between the two resistance states.

The select transistor ST is, for example, an n-type metal-oxide-semiconductor field-effect transistor (MOSFET).

The magnetoresistance effect element VR is coupled to a bit line BL at its first end, and is coupled to a first end (the source or drain) of the select transistor ST at its second end. The second end (the drain or source) of the select transistor ST is coupled to another bit line /BL. The gate of the select transistor ST is coupled to the word line WL, and the source is coupled to the bit line /BL.

### 1.2 Structure (Configuration)

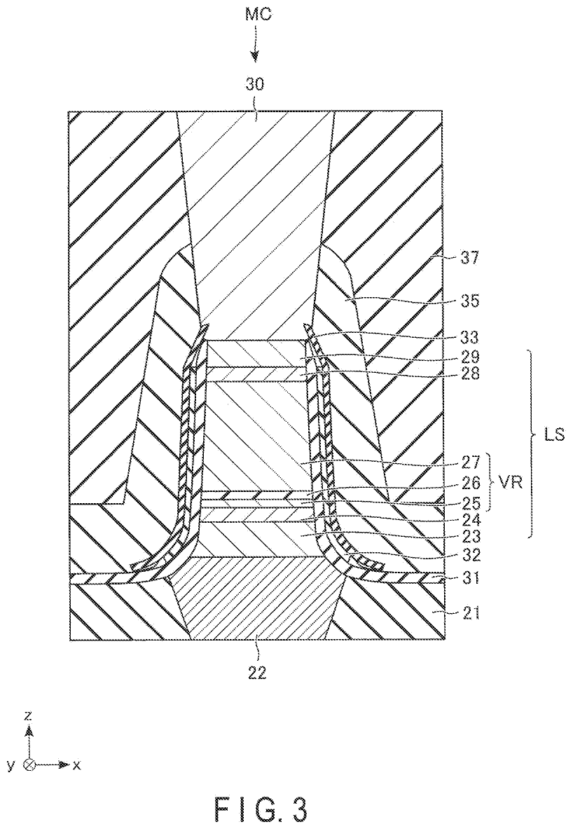

FIG. 3 shows a partial cross-sectional structure of a memory cell MC according to the first embodiment, showing, in particular, a cross-sectional structure of a magnetoresistance effect element VR and its peripheral components.

As shown in FIG. 3, the memory cell MC includes a magnetoresistance effect element VR, and the magnetoresistance effect element VR includes at least a ferromagnet (ferromagnetic layer) 25, an insulator (insulating layer) 26, and a ferromagnet (ferromagnetic layer) 27. The memory cell MC may include one or more additional layers, and FIG. 3 and the description that follows relate to an example in which the memory cell includes a lower electrode 22, a buffer layer 23, a foundation layer 24, a capping layer 28, a hard mask 29, and an upper electrode 30. The memory cell MC may include one or more additional layers, and/or each layer in the memory cell MC may be configured of a plurality of sub layers.

The lower electrode 22 is located in the interlayer insulator 21 above a semiconductor substrate (not illustrated), and is coupled to, at its bottom surface, a select transistor ST (not illustrated). The lower electrode 22 contains one or more of copper (Cu), scandium (Sc), titanium (Ti), zirconium (Zr), hafnium (Hf), tantalum (Ta), and tungsten (W).

An upper surface of the lower electrode 22 is electrically coupled to the ferromagnet 25. Based on the present example, the lower electrode 22 is electrically coupled to the ferromagnet 25 via the buffer layer 23 and the foundation layer 24. The buffer layer 23 is provided on an upper surface of the lower electrode 22, the foundation layer 24 is provided on an upper surface of the buffer layer 23, and the ferromagnet 25 is provided on an upper surface of the foundation layer 24.

The buffer layer 23 is a conductor layer such as a metal layer, and contains at least one of, for example, aluminum (Al), beryllium (Be), magnesium (Mg), calcium (Ca), hafnium (Hf), strontium (Sr), barium (Ba), scandium (Sc), yttrium (Y), lanthanum (La), zirconium (Zr), etc. The buffer layer 23 may contain at least one of the compounds such as HfB, MgAlB, HfAlB, ScAlB, ScHfB, and HfMgB.

The foundation layer 24 is a conductor layer, and may contain, for example, at least one of the compounds such as HfB, MgAlB, HfAlB, ScAlB, ScHfB, and HfMgB.

The ferromagnet 25 may have a structure including only a single ferromagnet, or may have a structure in which a plurality of ferromagnets and one or more conductors are stacked. The ferromagnet 25 may contain, for example, CoFeB, MgFeO, or a stack thereof. The ferromagnet 25 has an easy magnetization axis along a direction penetrating interfaces between the ferromagnet 25, the insulator 26, and the ferromagnet 27, such as an easy magnetization axis along a direction orthogonal to the interfaces. The magnetization direction of the ferromagnet 25 can be changed by data writing to the memory cell MC, and the ferromagnet 25 can function as a so-called “storage layer”.

The insulator 26 includes or is formed of, for example, MgO or AlO. The insulator 26 can function as a so-called “tunnel barrier”.

The ferromagnet 27 may have a structure including only a single ferromagnet, or may have a structure in which a plurality of ferromagnets and one or more conductors are stacked. The ferromagnet 27 may contain, for example, TbCoFe with perpendicular magnetic anisotropy, an artificial lattice in which Co and Pt are stacked, and an L1₀-ordered FePt alloy. The ferromagnet 27 has an easy magnetization axis along a direction penetrating interfaces between the ferromagnet 25, the insulator 26, and the ferromagnet 27, such as an easy magnetization axis along a direction orthogonal to the interfaces. The direction of magnetization of the ferromagnet 27 is intended to remain unchanged even when data is read from the memory cell MC or written into the memory cell MC. The ferromagnet 27 can function as a so-called reference layer.

When the magnetization direction of the ferromagnet 25 is parallel to the magnetization direction of the ferromagnet 27, the variable resistance element VR is in a state of having a lower resistance. When the magnetization direction of the ferromagnet 25 is anti-parallel to the magnetization direction of the ferromagnet 27, the variable resistance element VR is in a state of having a higher resistance.

For data reading, it is determined which of two resistance states a magnetoresistance effect element VR of a memory cell MC to be a data read target is in, using a read current flowing through a memory cell MC to be a data read target.

When a certain amount of write current IW_{P} flows from the ferromagnet 25 to the ferromagnet 27, the magnetization direction of the ferromagnet 25 becomes parallel to the magnetization direction of the ferromagnet 27. In contrast, when a different amount of write current IW_{AF} flows from the ferromagnet 27 to the ferromagnet 25, the magnetization direction of the ferromagnet 25 becomes anti-parallel to the magnetization direction of the ferromagnet 27.

The ferromagnet 27 is electrically coupled to a bottom surface of the upper electrode 30. Based on the present example, the ferromagnet 27 is electrically coupled to the upper electrode 30 via the capping layer 28 and the hard mask 29. The capping layer 28 is provided on an upper surface of the ferromagnet 27, and the hard mask 29 is provided on an upper surface of the capping layer 28.

The capping layer 28 is a conductor layer such as a metal layer, and contains, for example, at least one of Ta, Ru, Pt, and W. The hard mask 29 is, for example, a metal layer.

The upper electrode 30 is provided on an upper surface of the hard mask 29.

A set of components from a component that is on an upper surface of the lower electrode 22 to a component that is in contact with a bottom surface of the upper electrode 30, namely, a set of the buffer layer 23, the foundation layer 24, the ferromagnet 25, the insulator 26, the ferromagnet 27, the capping layer 28, and the hard mask 29 in the present example may be referred to as a layer stack LS.

A side surface of the magnetoresistance effect element VR is covered with an insulating layer 31. The insulating layer 31 may cover the entire side surface of the layer stack LS, and may cover, at its lower portion, an upper surface of the interlayer insulator 21, in contact with part of the upper surface of the lower electrode 22. The accompanying drawings and the description that follows are based on this example. The insulating layer 31 contains, for example, a nitride or an oxide.

A portion of a side surface of the insulating layer 31 that is on at least a side surface of the magnetoresistance effect element VR is covered with a nitride blocking layer 32. The nitride blocking layer 32 may cover a portion of the side surface of the insulating layer 31 that is on a side surface of an additional layer. The nitride blocking layer 32 covers, for example, a portion of the side surface of the insulating layer 31 that is on a side surface of the buffer layer 23, the foundation layer 24, the ferromagnet 25, the insulator 26, the ferromagnet 27, and the capping layer 28. The accompanying drawings and the description that follows are based on this example. The nitride blocking layer 32 aims to suppress, for example, the effects of nitride that is generated in a manufacturing process of the memory cell MC that will be described later. For this purpose, an easily nitridable material is adopted. Specifically, the nitride blocking layer 32 contains, for example, one or more of Mg, Ti, Zr, niobium (Nb), Ta, Al, and gadolinium (Gd), and an oxide of Mg, Ti, Zr, Nb, Ta, Al, or Gd. The nitride blocking layer 32 may have a tendency to be continuously formed, namely, a tendency not to be intermittent.

A protective layer 33 is provided on a side surface of the nitride blocking layer 32. The protective layer 33 may cover, for example, the entire side surface of the nitride blocking layer 32. An area of an opening at an upper end of the protective layer 33 is smaller than an area of an opening at an upper end of the nitride blocking layer 32. Accordingly, a portion of the protective layer 33 including its upper end projects to the inside of the opening at the upper end of the nitride blocking layer 32, and covers an upper surface of the nitride blocking layer 32. Accordingly, the nitride blocking layer 32 is not in contact with the upper electrode 30.

FIG. 3 shows an example in which the center of the upper electrode 30 in an xy plane matches the center of the layer stack LS in the xy plane; however, the center of the upper electrode 30 in the xy plane may be greatly deviated from the center of the layer stack LS in the xy plane. In this case, a portion of an upper surface of the hard mask 29 is located above an upper surface of the protective layer 33, and an inner surface of the protective layer 33 is in contact with a side surface of the hard mask 29. The protective layer 33 contains or is formed of a material with an etching rate different from the etching rates of a capping nitride layer 35 and an interlayer insulator 37 (to be described below). The protective layer 33 is, for example, a metal layer, and contains, for example, at least one of Ta, Ru, Pt, and W.

The side surface of the protective layer 33, a lower portion of the side surface of the upper electrode 30, and a portion of the insulating layer 31 that is not covered with the nitride blocking layer 32 are covered with a capping nitride layer 35.

Portions of a surface of the protective layer 33 and the side surface of the upper electrode 30 that are not covered with the capping nitride layer 35 are covered with an interlayer insulator 37.

### 1.3. Manufacturing Method

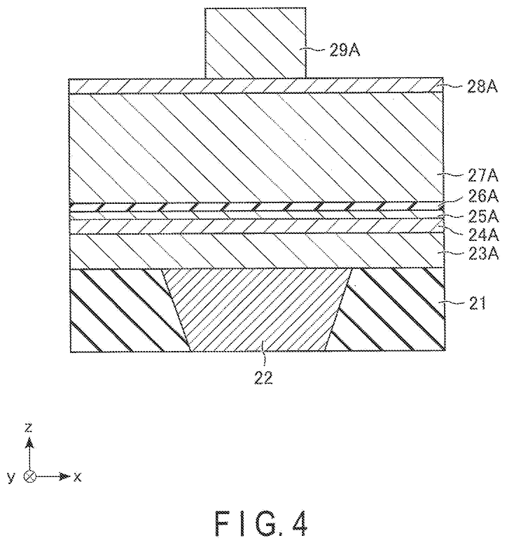

FIGS. 4 to 8 sequentially show states of a partial structure (which is the same as the part shown in FIG. 3) of the memory cell MC of the first embodiment in the respective manufacturing steps.

As shown in FIG. 4, a lower electrode 22 is formed in an interlayer insulator 21. Subsequently, a buffer layer 23A, a foundation layer 24A, a ferromagnet 25A, an insulator 26A, a ferromagnet 27A, and a capping layer 28A are stacked in this order on an upper surface of the interlayer insulator 21 and an upper surface of the lower electrode 22. The buffer layer 23A, the foundation layer 24A, the ferromagnet 25A, the insulator 26A, the ferromagnet 27A, and the capping layer 28A are components that are to be formed into a buffer layer 23, a foundation layer 24, a ferromagnet 25, an insulator 26, a ferromagnet 27, and a capping layer 28, respectively.

Thereafter, a hard mask 29A is formed on an upper surface of the capping layer 28A. The hard mask 29A is a component that is to be deformed into a hard mask 29. The hard mask 29A remains in a region above a region in which a layer stack LS is to be formed, and includes an opening in the other regions.

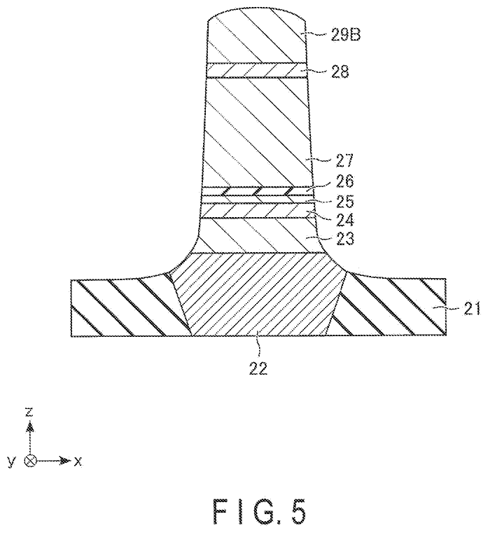

As shown in FIG. 5, the buffer layer 23A, the foundation layer 24A, the ferromagnet 25A, the insulator 26A, the ferromagnet 27A, and the capping layer 28A are partially removed through etching using the hard mask 29A as a mask. As a result, a buffer layer 23, a foundation layer 24, a ferromagnet 25, an insulator 26, a ferromagnet 27, and a capping layer 28 are formed. The etching may be performed by, for example, ion beam etching (IBE). The hard mask 29A, an upper surface of which is removed through the etching, becomes a hard mask 29B. Through the etching, portions of the upper surface of the lower electrode 22 and the upper surface of the interlayer insulator 21 that are located directly below the opening of the hard mask 29A are slightly lowered.

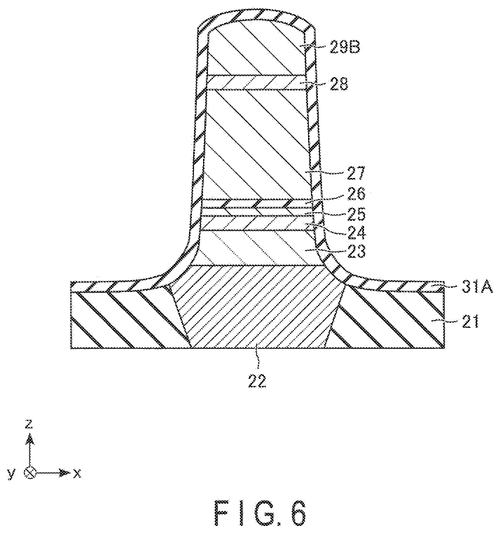

As shown in FIG. 6, an insulating layer 31A is formed on the entire upper surface of the structure obtained by the steps so far. The insulating layer 31A is a component that is to be formed into an insulating layer 31. The insulating layer 31A covers side surfaces of the buffer layer 23, the foundation layer 24, the ferromagnet 25, the insulator 26, the ferromagnet 27, the capping layer 28, the surface of the hard mask 29B, an exposed portion of an upper surface of the lower electrode 22, and an upper surface of the interlayer insulator 21.

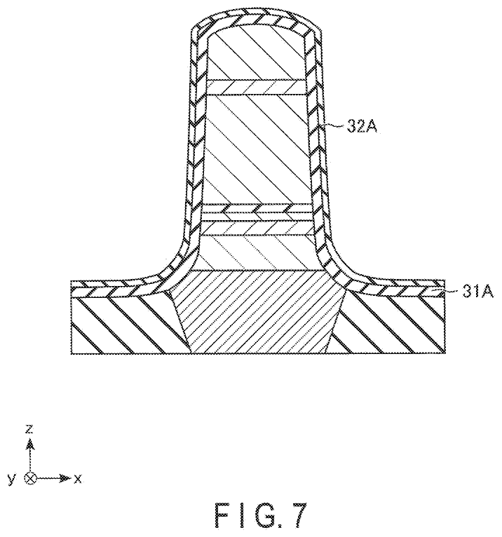

As shown in FIG. 7, a nitride blocking layer 32A is formed on the entire upper surface of the structure obtained by the steps so far. The nitride blocking layer 32A is a component that is to be formed into a nitride blocking layer 32. A surface of the insulating layer 31A is covered with the nitride blocking layer 32A.

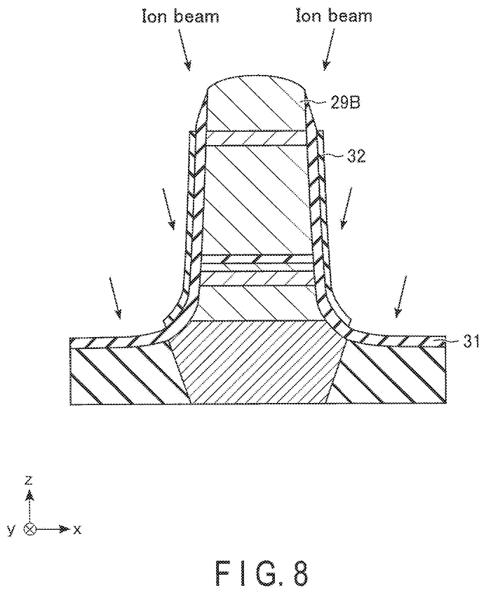

As shown in FIG. 8, first IBE is performed on a structure obtained by the steps so far. An angle of an ion beam used in the first IBE with respect to the z axis is small, and is, for example, equal to or greater than 10° and equal to or smaller than 20°. Through the etching with the ion beam at such an angle, the nitride blocking layer 32A, which is located at the outermost side, is partially removed. For example, an upper portion of the nitride blocking layer 32A such as a portion above a bottom surface of the hard mask 29B is removed by the first IBE. Also, a portion of the nitride blocking layer 32A that is above the interlayer insulator 21 is removed. Through the partial removal of the nitride blocking layer 32A, a nitride blocking layer 32 is formed.

Through the partial removal of the nitride blocking layer 32A, a portion of the insulating layer 31A such as a portion that is on a surface of the hard mask 29B is exposed. With the exposed portion subjected to the IBE, a portion of the insulating layer 31A that is on an upper surface of the hard mask 29B is removed, and the insulating layer 31A becomes an insulating layer 31.

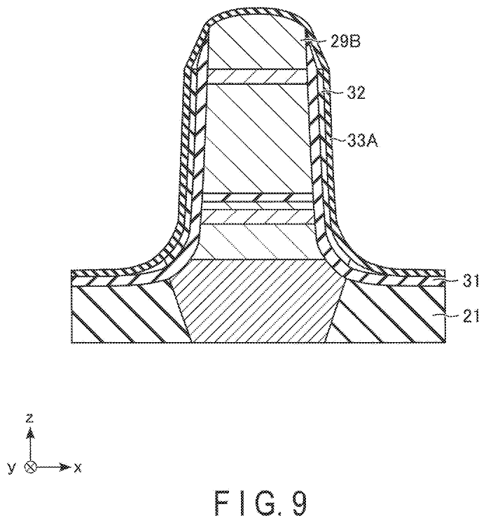

As shown in FIG. 9, a protective layer 33A is formed on the entire upper surface of the structure obtained by the steps so far. The protective layer 33A is a component that is to be formed into a protective layer 33. The protective layer 33A covers an exposed portion (i.e., an upper surface) of the hard mask 29B, an entire surface of the nitride blocking layer 32, and an exposed portion of the insulating layer 31 (i.e., a portion above the interlayer insulator 21).

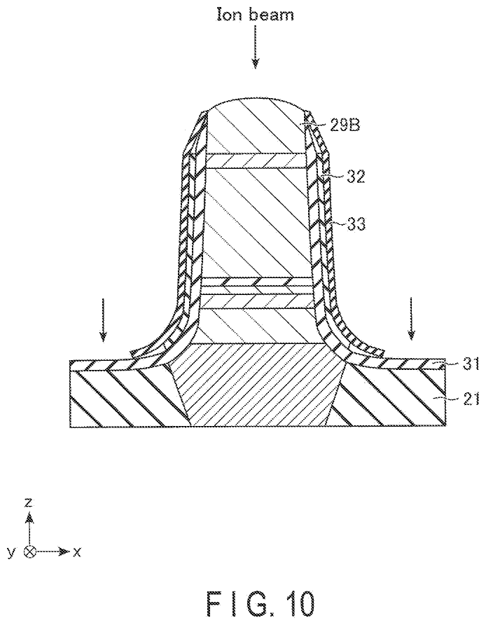

As shown in FIG. 10, second IBE is performed on a structure obtained by the steps so far. An angle of an ion beam used in the second IBE with respect to the z axis is smaller than that in the first IBE, and is, for example, equal to or greater than 0° and equal to or smaller than 10°. Through the ion beam etching at such an angle, the protective layer 33A, which is located on the outermost side, is partially removed. For example, a portion of the protective layer 33A that is on an upper surface of the hard mask 29B is removed by the second IBE, and the upper surface of the hard mask 29B is exposed. Through the partial removal of the protective layer 33A, a protective layer 33 is formed. In addition, a portion of the protective layer 33A that is on an upper surface of the insulating layer 31, namely, a portion above the interlayer insulator 21, may be removed by the second IBE.

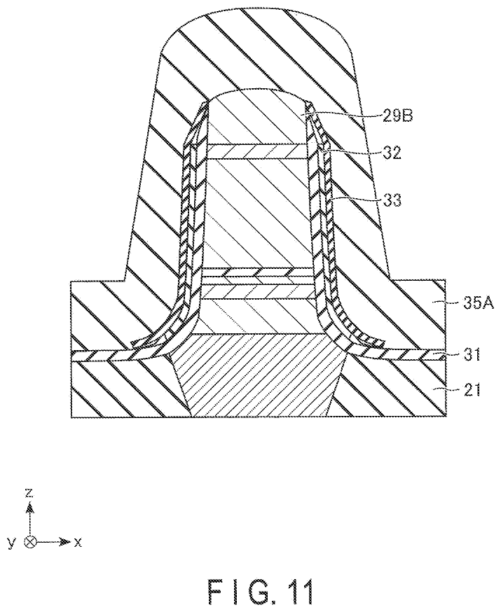

As shown in FIG. 11, a capping nitride layer 35A is formed on the entire upper surface of the structure obtained by the above-described steps. The capping nitride layer 35A is a component that is to be formed into a capping nitride layer 35. The capping nitride layer 35A covers the protective layer 33, an exposed portion (i.e., an upper surface) of the hard mask 29B, and an exposed portion of the insulating layer 31 (i.e., a portion above the interlayer insulator 21).

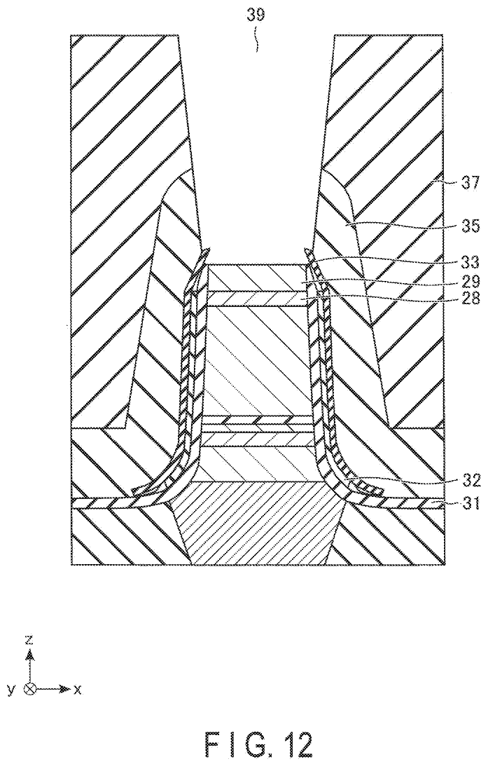

As shown in FIG. 12, an interlayer insulator 37 is formed on the entire upper surface of the structure obtained by the steps so far. The interlayer insulator 37 covers a capping nitride layer 35A. Subsequently, a hole 39 is formed in a region of the interlayer insulator 37 in which the upper electrode 30 is to be formed, through anisotropic etching such as lithography and reactive ion etching (RIE). Through this etching, an upper surface of the hard mask 29B is partially removed, and the hard mask 29B becomes a hard mask 29. The protective layer 33 has an etching rate lower than the etching rate of the capping nitride layer 35, the interlayer insulator 37, and the hard mask 29, with respect to the etching of FIG. 12. Accordingly, only a small portion of the protective layer 33 is removed by the etching of FIG. 12, and an upper end of the protective layer 33 remains in the hole 39. As described above, an area of an opening at an upper end of the protective layer 33 is smaller than an area of an opening at an upper end of the nitride blocking layer 32. In addition, the protective layer 33 is, for example, in contact with the insulating layer 31 and/or the hard mask 29 in the hole 39. Accordingly, the nitride blocking layer 32 is not exposed in the hole 39.

Next, a surface of the hole 39 is cleaned by a chemical. The chemical has a property of dissolving the nitride blocking layer 32. However, since the nitride blocking layer 32 is protected by the protective layer 33 so as not to be in contact with the hole 39, the nitride blocking layer 32 is suppressed from being exposed to the chemical for wet cleaning that is performed after a RIE process that opens the hole 39.

As shown in FIG. 3, an upper electrode 30 is formed by providing a conductor in the hole 39. As a result, the structure shown in FIG. 3 is completed.

### 1.4 Advantageous Effects

According to the first embodiment, it is possible to provide a magnetoresistance memory device 1 including a magnetoresistance effect element VR with a high reliability, as will be described below.

First, a magnetoresistance memory device for reference will be described. By providing a nitride blocking layer 132 corresponding to the nitride blocking layer 32 on a portion of a surface of the nitride layer 131 corresponding to the insulating layer 31 that is in contact with at least the magnetoresistance effect element VR, it is possible to suppress deterioration of the magnetic properties of the magnetoresistance effect element VR, as in the magnetoresistance memory device 1. It is considered that this is due to the effects of nitrogen from the capping nitride layer 135 corresponding to the capping nitride layer 35 on the surroundings, and suppression of such effects of nitrogen by the nitride blocking layer 132. To achieve a nitride blocking layer 132 with such a configuration, a structure in which a nitride blocking layer 132 is provided on a surface of the nitride layer 131 and a capping nitride layer 135 is provided on a surface of the nitride blocking layer 132 may be adopted. However, with such a structure, when a hole for an upper electrode corresponding to the step of FIG. 12 of the first embodiment is formed, the nitride blocking layer 132 will be exposed in the hole. Accordingly, the nitride blocking layer 132 may be dissolved by a chemical for wet cleaning of the hole. When such a chemical reaches a lateral portion on the side surface of the magnetoresistance effect element VR, the advantageous effect of the nitride blocking layer 132 of suppressing deterioration in magnetic properties of the magnetoresistance effect element VR cannot be obtained.

In the magnetoresistance memory device 1 according to the first embodiment, a protective layer 33 is provided on a surface of a nitride blocking layer 32. An area of an opening at an upper end of the protective layer 33 is smaller than an area of an opening at an upper end of the nitride blocking layer 32, and the protective layer 33 is at least more easily soluble in a chemical for wet cleaning of the hole 39 for the upper electrode 30 than the nitride blocking layer 32. Accordingly, the nitride blocking layer 32 is not exposed in the hole 39 during the wet cleaning of the hole 39, and is protected from being exposed to the chemical for wet cleaning. It is thus possible to maintain the nitride blocking layer 32 on the lateral portion on the side surface of the magnetoresistance effect element VR, thereby achieving a magnetoresistance effect element VR with high magnetic properties, compared to the structure of the magnetoresistance memory device for reference in which a nitride blocking layer 32 is not provided.

### 1.5. Modification

Embodiments have been described with respect to the example in which a magnetoresistance effect element VR has a structure in which a ferromagnet 25 that functions as a storage layer is located below the insulator 26 and the ferromagnet 27 that functions as a reference layer is located above the insulator 26. However, the first embodiment is not limited to this example. That is, the ferromagnet 27 may be located below the insulator 26, and the ferromagnet 25 may be located above the insulator 26.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistance memory device comprising:
a layer stack including a first ferromagnetic layer, a second ferromagnetic layer, and an insulating layer between the first ferromagnetic layer and the second ferromagnetic layer;
a first nitride on a side surface of the layer stack;
a first layer on a side surface of the first nitride;
a second layer on a side surface of the first layer, the second layer being in contact with the first layer at a position above an upper surface of the first layer;
a first electrode on the layer stack; and
a second nitride on a side surface of the second layer.

2. The magnetoresistance memory device according to claim 1, wherein
the first layer surrounds the side surface of the layer stack and includes, at an upper end, a first opening with a first area,
the second layer surrounds the side surface of the layer stack and includes, at an upper end, a second opening with a second area, and
the second area is smaller than the first area.

3. The magnetoresistance memory device according to claim 1, wherein
the first layer contains one or more of magnesium, titanium, zirconium, niobium, tantalum, aluminum, and gadolinium, and an oxide of magnesium, titanium, zirconium, niobium, tantalum, aluminum, or gadolinium.

4. The magnetoresistance memory device according to claim 1, wherein
the second layer has an opening above the layer stack.

5. The magnetoresistance memory device according to claim 4, wherein
an upper end of the second layer is located inside the first electrode.

6. The magnetoresistance memory device according to claim 1, wherein
the second layer contains ruthenium.

7. A method of manufacturing a magnetoresistance memory device, comprising:
forming a layer stack including a first ferromagnetic layer, a second ferromagnetic layer, and an insulating layer between the first ferromagnetic layer and the second ferromagnetic layer;
forming a first nitride on a surface of the layer stack;
forming a first layer on a surface of the first nitride;
removing a portion of the first nitride that is on an upper surface of the layer stack and a portion of the first layer that is on the upper surface of the layer stack to expose the upper surface of the layer stack;
forming a second layer on a surface of the first layer and on the upper surface of the layer stack;
removing a portion of the second layer that is on the upper surface of the layer stack to expose a portion of the layer stack;
forming a second nitride on a surface of the second layer and on the exposed portion of the layer stack; and
removing a portion of the second nitride that is on the layer stack to partially expose the layer stack.

8. The method according to claim 7, wherein
the removing of the portion of the second nitride that is on the layer stack includes first etching, and
an etching rate of the second layer against the first etching is lower than an etching rate of the second nitride against the first etching.

9. The method according to claim 7, wherein
the forming of the second layer includes forming the second layer from a position on a surface of the first layer to a position on an upper surface of the first nitride.

10. The method according to claim 7, wherein
the exposing of the portion of the layer stack includes leaving a portion of the second layer from a position on a surface of the first layer to a position on an upper surface of the first nitride.

11. The method according to claim 7, wherein
the exposing of the portion of the layer stack includes partially removing an upper surface of the layer stack.

12. The method according to claim 7, wherein
the first layer contains one or more of magnesium, titanium, zirconium, niobium, tantalum, aluminum, and gadolinium, and an oxide of magnesium, titanium, zirconium, niobium, tantalum, aluminum, or gadolinium.

13. The method according to claim 7, wherein
the second layer contains ruthenium.
